(19) United States
(12) Patent Application Publication
(10) Pub. No.: US 2025/0323080 A1
(43) Pub. Date: Oct. 16, 2025

(54) Semiconductor Treating Device

(71) Applicant: Hitachi High-Tech Corporation, Tokyo (JP)

(72) Inventors: Masahiro KAMIGAKI, Tokyo (JP); Motohiro TAKAHASHI, Tokyo (JP); Masashi FUJITA, Tokyo (JP)

(21) Appl. No.: 19/095,138

(22) Filed: Mar. 31, 2025

(30) Foreign Application Priority Data
Apr. 11, 2024 (JP) 2024-063976

(51) Int. Cl. H01L 21/68; B25J 11/00; H01L 21/687

(52) U.S. Cl. CPC H01L 21/681; B25J 11/0095; H01L 21/68707

(57) ABSTRACT

In a semiconductor treating device according to the disclosure, before a transport mechanism places a sample onto a sample stage, a position deviation amount from an ideal position of the sample is calculated using an angle or a position of the transport mechanism measured by a sensor, and the sample stage is operated by the position deviation amount.

### BACKGROUND OF THE INVENTION

### 1. Field of the Invention

The present disclosure relates to a sample transport method in a semiconductor treating device.

### 2. Description of Related Art

In a semiconductor treating device such as a charged particle beam device, a wafer transport robot is used to transport a sample such as a semiconductor wafer into the device. For example, a vacuum transport robot is used to transport a wafer from a load lock chamber (hereinafter referred to as an LC) for connection to an atmospheric pressure environment outside the device onto a sample stage in a sample chamber (hereinafter referred to as an SC) in a vacuum environment. At this time, the wafer transport robot is required to transport the wafer onto the sample stage with high accuracy every time it repeatedly operates.

PTL 1 discloses, as a method for transporting a wafer with high accuracy, a method for measuring wafer eccentricity in an LC and correcting a position of a sample stage based on the measured eccentricity to implement high-accuracy wafer transport.

### CITATION LIST

### Patent Literature

PTL 1: JP2012-114117A

### SUMMARY OF THE INVENTION

According to the technique disclosed in PTL 1, even when a wafer position is deviated in the LC, it is possible to implement the high-accuracy wafer transport without changing an operation of a transport robot. On the other hand, in the technique of the document, in a case where a positioning error of the wafer transport robot that transports the wafer from a preliminary exhaust chamber onto the sample stage occurs, the error cannot be corrected, and a problem arises in that the transport accuracy onto the sample stage deteriorates.

The invention has been made in view of the above problems, and an object of the invention is to correct a transport error caused by a transport robot that transports a sample to be treated by a semiconductor treating device, and to implement high-accuracy sample transport.

In a semiconductor treating device according to the disclosure, before a transport mechanism places a sample onto a sample stage, a position deviation amount from an ideal position of the sample is calculated using an angle or a position of the transport mechanism measured by a sensor, and the sample stage is operated by the position deviation amount.

According to the semiconductor treating device of the disclosure, it is possible to correct a transport error caused by a transport robot and implement high-accuracy sample transport. Other problems, configurations, effects, and the like of the disclosure become apparent from the following description of embodiments.

### BRIEF DESCRIPTION OF THE DRAWINGS

FIG. 1 is a configuration diagram of a semiconductor treating device according to Embodiment 1.

FIG. 2 is a schematic view of an in-vacuum wafer transport robot viewed from the side.

FIG. 3A is a plan view of the in-vacuum wafer transport robot in a state where an arm is extended.

FIG. 3B is a plan view of the in-vacuum wafer transport robot in a state where the arm is retracted.

FIG. 4 shows a state where a wafer is placed in an LC2.

FIG. 5 shows a state where evacuation in the LC2 is completed and the in-vacuum wafer transport robot extends the arm to pick up the wafer.

FIG. 6 shows a state where the in-vacuum wafer transport robot lifts the wafer from the state shown in FIG. 5 to retract the arm, and then rotates the entire robot to direct the in-vacuum wafer transport robot toward a sample stage.

FIG. 7 shows a state where the arm is extended by rotating an arm extension operation motor from the state shown in FIG. 6 and the wafer is transported onto the sample stage.

FIG. 8 is a top view showing a relationship between a motor positioning error and a wafer deviation amount.

FIG. 9 is a flowchart showing a method for correcting the wafer deviation amount and a wafer transport method when the wafer is transported onto the sample stage.

### DESCRIPTION OF EMBODIMENTS

### Embodiment 1

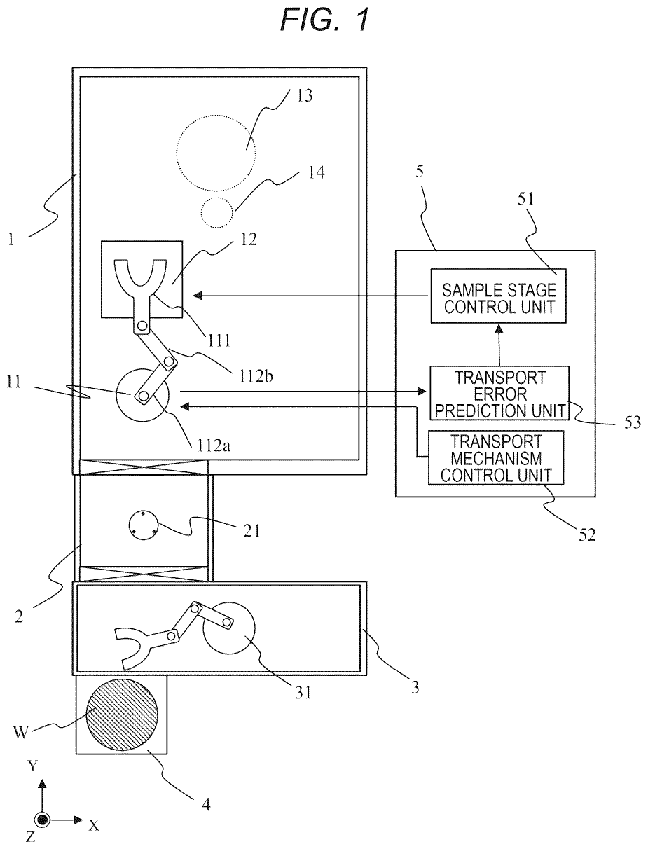

FIG. 1 is a configuration diagram of a semiconductor treating device according to Embodiment 1 of the disclosure. The semiconductor treating device of FIG. 1 is configured as a charged particle beam device that irradiates a sample (a semiconductor wafer in the following example) with a charged particle beam. The semiconductor treating device includes an SC1, an LC2, a mini-environment 3, and a computer 5.

The inside of the SC1 is in a vacuum state for irradiation with the charged particle beam. The SC1 includes an in-vacuum wafer transport robot 11 (transport mechanism), a sample stage 12, an electron gun 13 for irradiating a wafer with a charged particle beam, and an optical microscope 14 for performing observation and alignment at a low magnification.

The LC2 is a preliminary exhaust chamber for connecting the SC1 in a vacuum environment and the mini-environment 3 in an atmospheric environment. The LC2 becomes the vacuum environment when connected to the inside of the SC1, and becomes the atmospheric environment when connected to the mini-environment 3. A prealigner 21 that measures eccentricity of a wafer W placed in the LC2 is provided in the LC2.

The mini-environment 3 includes a transport robot 31 for transporting the wafer W stored in a front-opening unified pod (FOUP) 4 to the LC2.

The computer 5 includes a sample stage control unit 51 that controls the sample stage 12, a transport mechanism control unit 52 that controls the in-vacuum wafer transport robot 11, and a transport error prediction unit 53 that predicts a wafer transport error generated by the in-vacuum wafer transport robot 11.

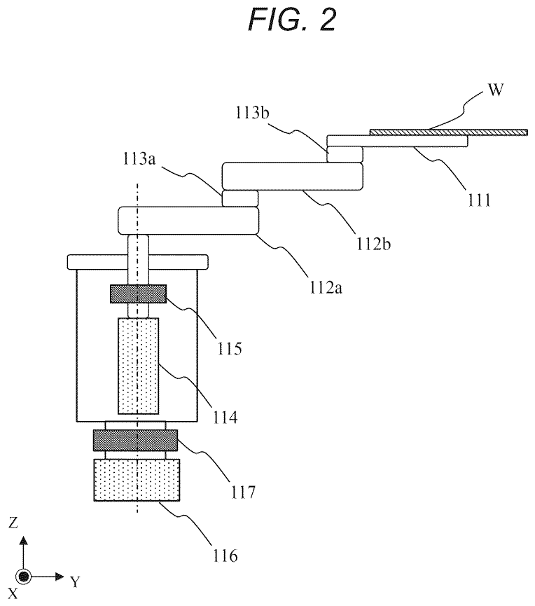

FIG. 2 is a schematic view of the in-vacuum wafer transport robot 11 viewed from the side. The in-vacuum wafer transport robot 11 includes the following: a hand 111 on which the wafer W is placed; a plurality of links 112a and 112b that transmit a power of a motor; a joint 113a and a joint 113b rotatably restrained between the link 112a and the link 112b and between the link 112b and the hand 111; an arm extension operation motor 114; an angle sensor 115 that measures an output angle of the arm extension operation motor 114; an overall rotation motor 116; and an angle sensor 117 that measures an output angle of the overall rotation motor 116.

A pulley and a steel belt (not shown) for transmitting the power of the motor are provided inside the links 112a and 112b. When the arm extension operation motor 114 is rotated, the power is transmitted by the steel belt, the joints 113a and 113b rotate, and the hand 111 operates in a Y direction.

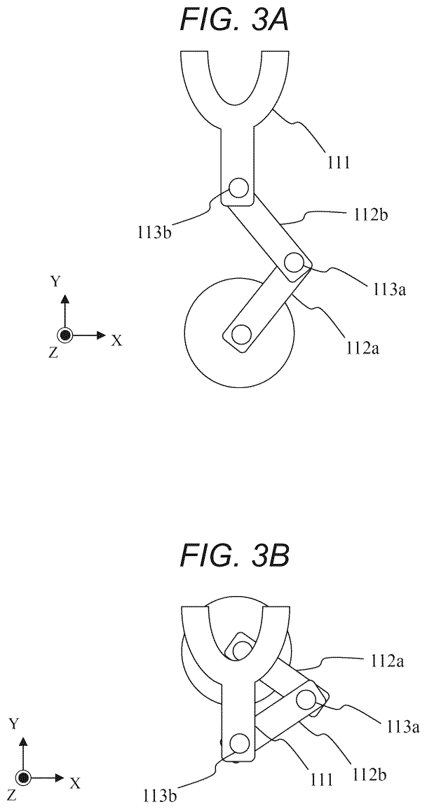

FIG. 3A is a plan view of the in-vacuum wafer transport robot 11 in a state where an arm is extended. FIG. 3B is a plan view of the in-vacuum wafer transport robot 11 in a state where the arm is retracted. The state of FIG. 3A and the state of FIG. 3B can be switched by the rotation of the arm extension operation motor 114, whereby the wafer W on the hand 111 can be transported in the Y direction. When the overall rotation motor 116 is rotated, a direction in which the hand 111 faces can be changed.

As the arm extension operation motor 114 and the overall rotation motor 116, a stepping motor capable of easily implementing positioning may be used, or a servo motor such as a direct drive motor capable of high-accuracy positioning may be used.

It is effective to use, for example, a rotary encoder as the angle sensors 115 and 117. It is necessary to use a rotary encoder having a resolution corresponding to a desired transport accuracy. When a speed reducer, a belt, or the like is used in the arm extension operation motor 114 and the overall rotation motor 116, it is effective to provide these sensors on the side closer to the wafer than the speed reducer and the belt. Accordingly, even when disturbance such as friction received by the in-vacuum wafer transport robot 11 is received during operation, a positioning error due to the disturbance can be measured.

In order to lift and place the wafer, the entire in-vacuum wafer transport robot 11 can move up and down. The entire in-vacuum wafer transport robot 11 is driven by, for example, a ball screw (not shown).

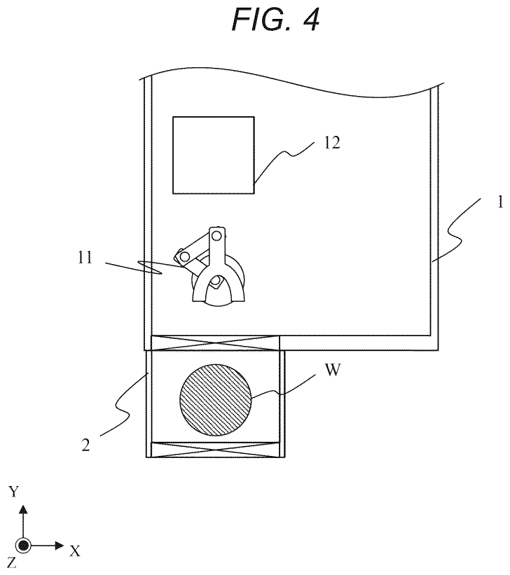

Next, an operation of transporting the wafer W from the LC2 onto the sample stage 12 by the in-vacuum wafer transport robot 11 will be described with reference to FIGS. 4 to 7.

FIG. 4 shows a state where the wafer W is placed in the LC2. At this time, the inside of the LC2 becomes the vacuum environment in order to be connected to the SC1, and the in-vacuum wafer transport robot 11 faces the direction of the LC2, in a state where the arm is retracted, and stands by.

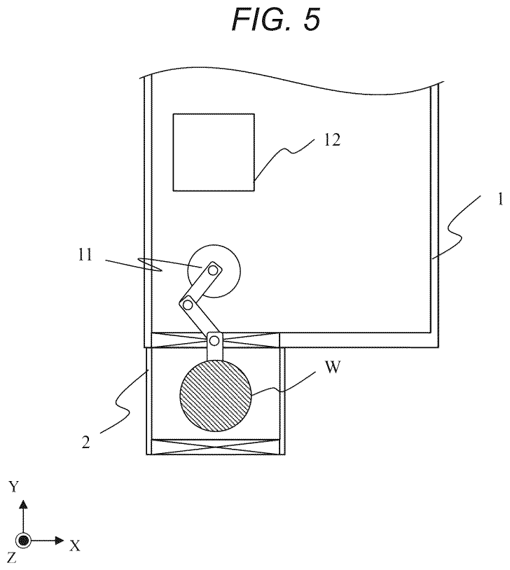

FIG. 5 shows a state where evacuation in the LC2 is completed and the in-vacuum wafer transport robot 11 extends the arm to pick up the wafer W.

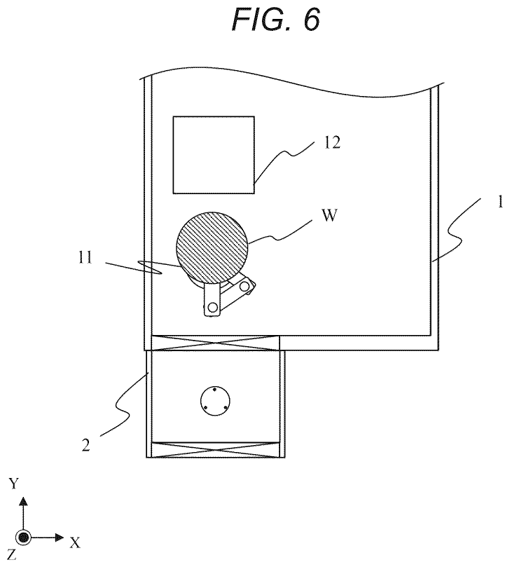

FIG. 6 shows a state where the in-vacuum wafer transport robot 11 lifts the wafer W from the state shown in FIG. 5 to retract the arm, and then rotates the entire robot to direct the in-vacuum wafer transport robot 11 toward the sample stage 12.

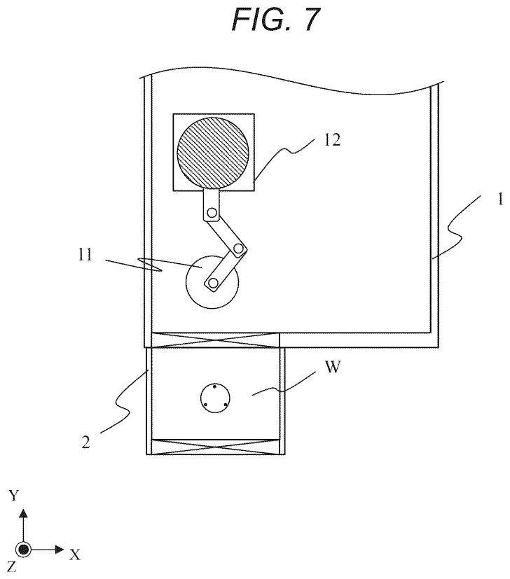

FIG. 7 shows a state where the arm is extended by rotating the arm extension operation motor 114 from the state shown in FIG. 6 and the wafer W is transported onto the sample stage 12. By lowering the entire robot from this state, the wafer placement onto the sample stage 12 is completed.

In a method in the related art, when the wafer is lifted in FIG. 5, there is a positioning error of the arm extension operation motor 114 and the overall rotation motor 116, and the position where the wafer W is placed on the hand 111 deviates from a predetermined position due to the error. Similarly, when the wafer is placed on the sample stage in FIG. 7, the wafer W is deviated from the predetermined position on the sample stage 12 due to the positioning error of the arm extension operation motor 114 and the overall rotation motor 116, and the wafer transport accuracy onto the sample stage 12 deteriorates.

Therefore, in the embodiment, a wafer deviation amount is predicted based on these motor positioning errors, and the sample stage 12 is operated by a deviation amount to correct the errors, thereby implementing high-accuracy wafer transport.

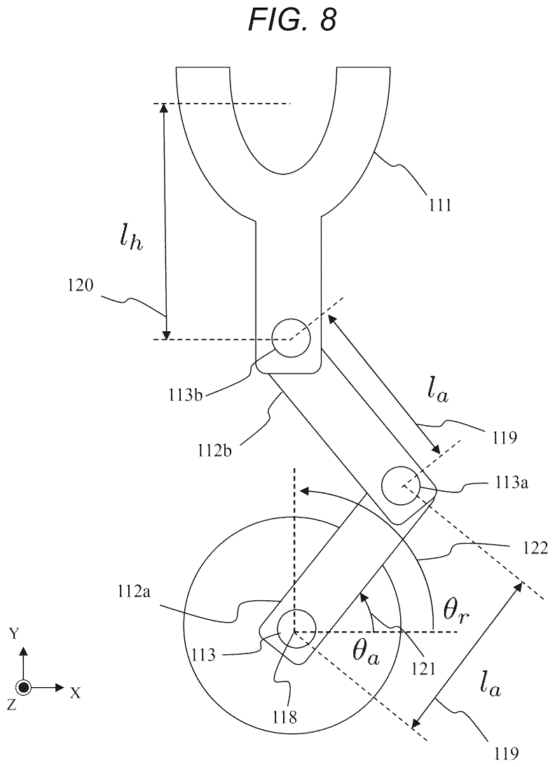

FIG. 8 is a top view showing a relationship between the motor positioning error and the wafer deviation amount. FIG. 8 is a diagram showing a definition of a length and an angle of each part in the in-vacuum wafer transport robot 11, and shows a length 119 (la) and a hand length 120 (lh) of the links 112a and 112b, an angle 121 (θa) of the arm extension operation motor 114, and an angle 122 (θr) of the overall rotation motor. Positions x and y (hereinafter referred to as a hand center position) of a center of the wafer when the wafer is correctly mounted on the hand 111 with reference to an origin 118 in FIG. 8 can be expressed by Formulas 1 and 2 using these lengths and angles.

$$x = ( 2 {l}_{a} sin {θ}_{a} + {l}_{h} ) cos {θ}_{r} \qquad Formula 1$$

$$y = ( 2 {l}_{a} sin {θ}_{a} + {l}_{h} ) sin {θ}_{r} \qquad Formula 2$$

Formulas 1 and 2 are relational formulas based on the assumption that there is no angle transmission error in parts of the joints 113a and 113b. In the in-vacuum wafer transport robot 11 to which the embodiment is applied, when an angle transmission error of a joint occurs, it is preferable to use a formula in consideration of the angle transmission error. It is also effective to measure the transmission error by additionally providing an angle sensor at the parts of the joints 113a and 113b.

By using the relational formulas of Formulas 1 and 2, deviation amounts Δx and Δy of the hand center position from the ideal position generated when the arm is extended as shown in FIG. 3A can be expressed as Formulas 3 and 4. A superscript cmd expresses a command value from the computer 5, and a superscript res expresses an output value (an actual value detected by the sensor).

$$Δ x = ( 2 {l}_{a} sin {θ}_{a}^{res} + {l}_{h} ) cos {θ}_{r}^{res} - ( 2 {l}_{a} sin {θ}_{a}^{cmd} + {l}_{h} ) cos {θ}_{r}^{cmd} \qquad Formula 3$$

$$Δ y = ( 2 {l}_{a} sin {θ}_{a}^{res} + {l}_{h} ) sin {θ}_{r}^{res} - ( 2 {l}_{a} sin {θ}_{a}^{cmd} + {l}_{h} ) sin {θ}_{r}^{cmd} \qquad Formula 4$$

When there is no positioning error of the motor, that is, when the command value and the output value are the same, Δx and Δy are zero. The command value is determined based on a position where the wafer is desired to be transported in the design of the device, and the output value is measured by the angle sensors 115 and 117 attached to the in-vacuum wafer transport robot 11.

Although Formulas 3 and 4 express the deviation of the center of the hand 111 focusing only on the positioning error of the motor, for example, when a temperature change is large, it is also effective to incorporate the fluctuation of the link length 119 (la) according to the temperature into a prediction formula. Instead of the prediction using the formulas as in Formulas 3 and 4, a wafer transport operation by the in-vacuum wafer transport robot 11 may be repeatedly performed at the time of adjusting the device or the like, and data of a motor angle and a wafer position may be acquired to model a prediction formula of the hand position based on the motor angle.

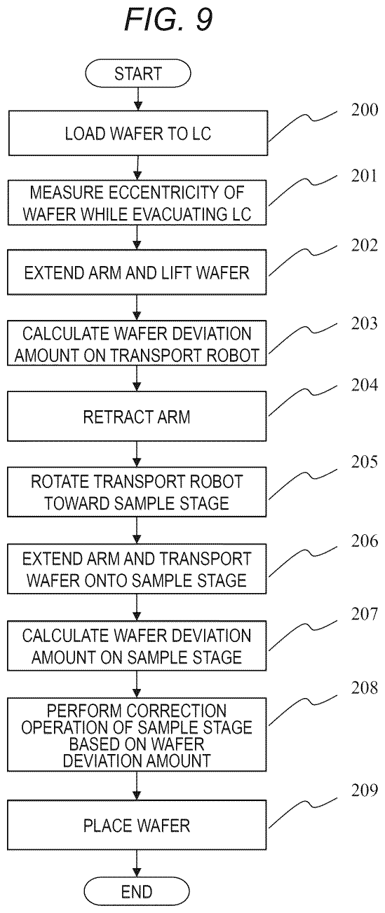

FIG. 9 is a flowchart showing a method for correcting the wafer deviation amount and a wafer transport method when the wafer W is transported onto the sample stage 12. This flowchart is performed by the computer 5. The flow of treating based on FIG. 9 is as follows.

Step 200: The transport robot 31 in the mini-environment 3 transports the wafer W into the LC2.

Step 201: The eccentricity (Δxp, Δyp) of the wafer W is measured using the prealigner 21 while evacuating the LC2. At this time, the in-vacuum wafer transport robot 11 stands by in the state of FIG. 4.

Step 202: As shown in FIG. 5, the arm extension operation motor 114 of the in-vacuum wafer transport robot 11 is driven to extend the arm into the LC2 and lift the wafer W.

Step 203: When the wafer W is lifted in step 202, the output angle of the arm extension operation motor 114 and the output angle of the overall rotation motor 116 are measured by the angle sensors 115 and 117, respectively. The transport error prediction unit 53 calculates, by using Formulas 3 and 4, the deviation (Δxu, Δyu) of the center position of the hand 111 at the time of lifting the wafer. By matching with the eccentricity in step 201, it can be calculated that the wafer W lifted up in step 202 and on the hand 111 is deviated from the center by (Δxp+Δxu, Δyp+Δyu).

Step 204: The arm extension operation motor 114 of the in-vacuum wafer transport robot 11 is operated to retract the arm.

Step 205: The in-vacuum wafer transport robot 11 is rotated toward the sample stage 12 using the overall rotation motor 116 to obtain the state shown in FIG. 6.

Step 206: The arm extension operation motor 114 of the in-vacuum wafer transport robot 11 is operated to extend the arm, and the wafer W is transported onto the sample stage 12 to obtain the state shown in FIG. 7.

Step 207: When the arm is extended in step 206, the output angle of the arm extension operation motor 114 and the output angle of the overall rotation motor 116 are measured using the angle sensors 115 and 117, respectively. The transport error prediction unit 53 calculates, by using Formulas 3 and 4, the deviation (Δxd, Δyd) of the center position of the hand 111 at this time. By matching with a position deviation amount of the wafer on the hand 111 in step 203, it can be calculated that the wafer W is deviated by (Δxp+Δxu+Δxd, Δyp+Δyu+Δyd) with respect to the center on the sample stage 12.

Step 208: The transport mechanism control unit 52 gives the wafer deviation amount (Δxp+Δxu+Δxd, Δyp+Δyu+Δyd) calculated in step 207 to the sample stage control unit 51 as a position command in XY directions, thereby performing a correction operation of the sample stage 12. By this correction operation, the errors calculated so far are offset.

Step 209: After the correction operation in step 208 is completed, the in-vacuum wafer transport robot 11 is lowered to place the wafer W onto the sample stage 12. Thereafter, the arm extension operation motor 114 is operated to retract the arm, thereby completing a series of wafer transport operations.

### Embodiment 1: Summary

In the semiconductor treating device according to Embodiment 1, before the in-vacuum wafer transport robot 11 places the wafer W onto the sample stage 12, the position deviation amount of the wafer W from the ideal position is calculated by Formulas 3 and 4 using the angles measured by the angle sensors 115 and 117. The computer 5 causes the sample stage 12 to move by the calculated position deviation amount. Accordingly, it is possible to reduce the positioning error when the in-vacuum wafer transport robot 11 places the wafer W onto the sample stage 12.

The semiconductor treating device according to Embodiment 1 measures the eccentricity (Δxp, Δyp) of the wafer W using the prealigner 21. Further, the deviation (Δxu, Δyu) of the center position of the hand 111 when the wafer W is lifted and the deviation (Δxd, Δyd) of the center position of the hand 111 when the wafer W is placed onto the sample stage 12 are calculated. The computer 5 calculates the position deviation amount of the wafer W with respect to the center on the sample stage 12 by summing these deviations. Accordingly, it is possible to correct the position deviation when the in-vacuum wafer transport robot 11 receives the wafer W and the in-vacuum wafer delivers the wafer W, respectively.

### Embodiment 2

In Embodiment 2 of the disclosure, a configuration example that can be implemented in addition to the configuration described in Embodiment 1 will be described. Configurations other than those described below are the same as those described in Embodiment 1.

After step 209, an alignment operation of measuring a position where the wafer W is actually placed is performed by the optical microscope 14. At this time, in a case where a phenomenon, such as sliding of the wafer W on the hand 111 or occurrence of an abnormality in a mechanism such as occurrence of loosening of a steel belt of the in-vacuum wafer transport robot 11, occurs due to the operation of the in-vacuum wafer transport robot 11 when the wafer W is held, it is conceivable that the wafer position is deviated even though the wafer position deviation is corrected in step 207. In such a case, it is preferable that an allowable value of the deviation amount is set in advance, and when the wafer deviation equal to or larger than the allowable value occurs, an alert is issued to notify a device user.

It is also effective to predict an abnormality occurring in the device and change the operation according to an actual wafer deviation amount measured by the optical microscope 14. For example, when the wafer is largely deviated only in the Y direction on coordinate axes shown in FIG. 1, it is assumed that the wafer slides on the hand 111, and the operation of extending the arm in step 206 is delayed, so that the device can be operated without stopping while preventing the sliding. At this time, since a throughput of the device decreases, it is necessary to notify the device user that the device is operating at a low speed. It is also effective to assume that an abnormality has occurred in the mechanism of the in-vacuum wafer transport robot 11 when there is a large deviation in both XY directions, and to issue an alert to notify the device user that maintenance is necessary.

After the wafer W is transported onto the stage in step 206, the motor angle may be measured in real time by the angle sensor 115 of the arm extension operation motor. At this time, for example, when the measured angle is vibrational, it is possible to ensure the transport accuracy by not performing the calculation of the wafer deviation amount in step 207 or the wafer placing operation in step 209 until the vibration is attenuated. At this time, it is effective to wait until the vibration is attenuated to a predetermined amplitude or less. This is because, when a base of the arm is vibrating, the vibration propagates to a tip portion of the arm and the position accuracy is likely to decrease, and thus it is desirable to wait until the vibration ends.

After the wafer is transported onto the stage in step 206, it is also assumed that the angle measured by the angle sensor 115 is not vibrated but gradually deviated. In this case, a wafer position may be predicted using Formulas 3 and 4 according to a drift amount, and the sample stage 12 may be operated at the same speed based on the predicted wafer position, and then step 207 and the subsequent steps may be performed. Accordingly, it is possible to improve the transport accuracy while maintaining the transport speed.

### Regarding Modification of Disclosure

The disclosure is not limited to the above-described embodiments, and includes various modifications. For example, the above embodiments are described in detail to describe the disclosure in an easy-to-understand manner and are not necessarily limited to including all the described configurations. A part of a configuration of a certain embodiment can be replaced with a configuration of another embodiment, and a configuration of another embodiment can also be added to a configuration of a certain embodiment. In addition, another configuration can be added to a part of a configuration of each embodiment, and the part of the configuration of each embodiment can be deleted or replaced with another configuration.

In the above embodiments, an example in which the semiconductor treating device is configured as a charged particle beam device has been described, but the disclosure is also applicable to other semiconductor treating devices in which a transport mechanism transports a semiconductor sample to and from a sample stage.

In the above embodiments, although it has been described that the angle sensors 115 and 117 are used as sensors for detecting a posture (a rotation angle of the arm) of the in-vacuum wafer transport robot 11, other sensors may be used as long as a position of the sample held by the in-vacuum wafer transport robot 11 can be calculated. For example, in a configuration example in which the arm provided in the in-vacuum wafer transport robot 11 is driven by a linear motor, a sensor that measures at least one of a planar position of a hand and a planar position of the arm may be provided, and the position of the sample may be calculated based on the detection result. A calculation formula in this case is a formula describing a relationship between the planar position detected by the sensor and the sample position, instead of Formulas 3 and 4.

In the above embodiments, each unit of the computer 5 may be implemented by hardware such as a circuit device in which functions of the units are mounted, or may be implemented by an arithmetic unit such as a central processing unit (CPU) executing software in which the functions of the units are mounted.

The structure of the in-vacuum wafer transport robot 11 described in the above embodiments is an example, and it is preferable to use an optimum structure according to the device to which the disclosure is applied. For example, instead of transmitting power by a steel belt, a motor may be embedded in a joint portion 113 of the link and driven.

What is claimed is:

1. A semiconductor treating device for treating a sample of a semiconductor, the semiconductor treating device comprising:
a sample stage on which the sample is placed;
a transport mechanism configured to transport the sample to and from the sample stage;
a sensor configured to detect an angle of the transport mechanism or a position of the transport mechanism; and
a computer configured to control the transport mechanism, wherein
the computer calculates a position deviation amount from an ideal position of the sample using the angle or the position measured by the sensor before the transport mechanism places the sample onto the sample stage, and
the computer operates the sample stage by the position deviation amount to reduce a positioning error when the transport mechanism places the sample onto the sample stage.

2. The semiconductor treating device according to claim 1, wherein
the transport mechanism includes an arm that rotates about a rotation shaft,
the sensor measures, as the angle, a rotation angle of the arm about the rotation shaft, and
the computer calculates the position deviation amount according to a relational formula among the angle, a length of the arm, and a position of the sample.

3. The semiconductor treating device according to claim 1, wherein
the transport mechanism includes an arm movable in a plane and a hand that holds the sample,
the sensor measures a planar position of the arm or a planar position of the hand as the position, and
the computer calculates the position deviation amount according to a relational formula between the position and a position of the sample.

4. The semiconductor treating device according to claim 1, further comprising:
a prealigner configured to measure eccentricity of the sample when the sample is stationary before the sample is transported to a sample chamber accommodating the sample stage, wherein
the computer calculates, using the angle or the position, a position deviation of the sample generated when the transport mechanism receives the sample as a reception-time deviation, and
the computer calculates the position deviation amount by adding the eccentricity measured by the prealigner and the reception-time deviation.

5. The semiconductor treating device according to claim 1, further comprising:
a prealigner configured to measure eccentricity of the sample when the sample is stationary before the sample is transported to a sample chamber accommodating the sample stage, wherein
the computer calculates, using the angle or the position, a position deviation of the sample generated when the transport mechanism places the sample onto the sample stage as a delivery-time deviation, and
the computer calculates the position deviation amount by adding the eccentricity measured by the prealigner and the delivery-time deviation.

6. The semiconductor treating device according to claim 1, wherein
the computer acquires, as an actual deviation amount, a result obtained by actually measuring a deviation from the ideal position of the sample, and
when a difference between the actual deviation amount and the position deviation amount calculated using the angle or the position is equal to or larger than a threshold, the computer issues an alert.

7. The semiconductor treating device according to claim 1, wherein
the computer acquires, as an actual deviation amount, a result obtained by actually measuring a deviation from the ideal position of the sample, and
when the actual deviation amount is equal to or larger than a threshold, the computer makes a speed at which the transport mechanism transports the sample slower than when the actual deviation amount is less than the threshold.

8. The semiconductor treating device according to claim 1, wherein
when the angle measured by the sensor vibrates at an amplitude equal to or larger than a threshold before the sample is placed onto the sample stage, the transport mechanism does not perform an operation of placing the sample onto the sample stage until the amplitude is attenuated to be smaller than the threshold.

9. The semiconductor treating device according to claim 1, wherein
when the angle measured by the sensor is gradually deviated at a change rate equal to or higher than a threshold before the transport mechanism places the sample onto the sample stage, the computer moves the sample stage to follow the change rate.

10. The semiconductor treating device according to claim 1, wherein
the semiconductor treating device is configured as a charged particle beam device that irradiates the sample with a charged particle beam.
